(19) United States
(12) Patent Application Publication
(10) Pub. No.: US 2005/0218528 A1
(43) Pub. Date: Oct. 6, 2005

(54) Capillary underfill channel

(76) Inventors: John J. Beatty, Chandler, AZ (US); Timothy M. Takeuchi, Chandler, AZ (US)

Correspondence Address: SCHWEGMAN, LUNDBERG, WOESSNER & KLUTH, P.A., P.O. BOX 2938, MINNEAPOLIS, MN, 55402-0938, US

(21) Appl. No.: 10/815,564

(22) Filed: Mar. 31, 2004

(51) Int. Cl. H01L 21/48; H01L 29/40

(52) U.S. Cl. 257/778; 438/108; 257/777; 257/780; 257/786; 438/612

(57) ABSTRACT

An interposer, between a die and a substrate, has a body with a first surface, an opposite second surface, and a channel that passes from the first surface, through the body to the opposite second surface.

### TECHNICAL FIELD

Embodiments of the present invention relate to a packaged semiconductive die with integrated circuitry.

### BACKGROUND INFORMATION

An active surface of a first substrate, such as a flip-chip or an interposer, is subject to numerous electrical couplings that are usually brought to an edge of the first substrate. Heat generation is significant at the active surface of the first substrate. Electrical connections, referred variously to as balls, bumps, and others, are deposited as terminals on the active surface of a first substrate. The bumps include solders and/or plastics that make mechanical connections and electrical couplings to a second substrate, such as a printed wiring board or an interposer. The first substrate is inverted onto the second substrate with the bumps aligned to bonding pads on the second substrate. If the bumps are solder bumps, the solder bumps on the first substrate are soldered to the bonding pads on the second substrate.

Shear stress may exist on the solder joints during temperature cycling of the device. This shear stress is partially a result of a difference in the coefficients of thermal expansion (“CTE” ) of the first substrate and the second substrate.

It is desirable to reduce the shear stress on the solder joints to reduce failures.

### BRIEF DESCRIPTION OF THE DRAWINGS

FIG. 1A is a cross-section of an embodiment of a package during an underfill process;

FIG. 1B is a cross-section of the package depicted in FIG. 1A after further processing;

FIG. 1C is a cross-section of the package depicted in FIG. 1B after further processing;

FIG. 1D is a cross-section of the package depicted in FIG. 1C after further processing;

FIG. 1E is a cross-section of the package depicted in FIG. 1D after further processing;

FIG. 1F is a plan view of the package depicted in FIG. 1C to FIG. 1E;

FIG. 2A is a cross-section of an embodiment of a package during an underfill process;

FIG. 2B is a cross-section of the package depicted in FIG. 2A after further processing;

FIG. 2C is a cross-section of the package depicted in FIG. 2B after further processing;

FIG. 2D is a cross-section of the package depicted in FIG. 2C after further processing;

FIG. 2E is a cross-section of the package depicted in FIG. 2D after further processing;

FIG. 2F is a view of a meniscus in an interposer according to one embodiment of FIG. 2C.

FIG. 2G is a plan view of the package according to one embodiment of FIG. 2C;

FIG. 3A is a cross-section of a package according to one embodiment;

FIG. 3B is a plan view of the package according to one embodiment of FIG. 3A; and

FIG. 4 is a process flow diagram according to one embodiment of a method to dispense underfill for a package.

### DETAILED DESCRIPTION

The following description includes terms, such as “upper”, “lower”, “first”, “second”, etc. that are used for descriptive purposes only and are not to be construed as limiting. The embodiments of a device or article of the present invention described herein can be manufactured, used, or shipped in a number of positions and orientations. The term “die” generally refers to the physical object that is the basic workpiece that is transformed by various process operations into the desired integrated circuit device. A die is usually singulated from a wafer, and wafers may be made of semiconducting, non-semiconducting, or combinations of semiconducting and non-semiconducting materials. An “interposer” is often a ceramic structure.

One embodiment relates to a package that includes a die, a substrate, and an interposer there between. The interposer has a body and a channel that extends through the body. In a first embodiment, the channel is a vent hole in a die shadow region. In a second embodiment, the channel is a microchannel that lies outside of the die shadow region. In this embodiment, an underfill-mixture-reinforced solder joint is between the interposer and the substrate.

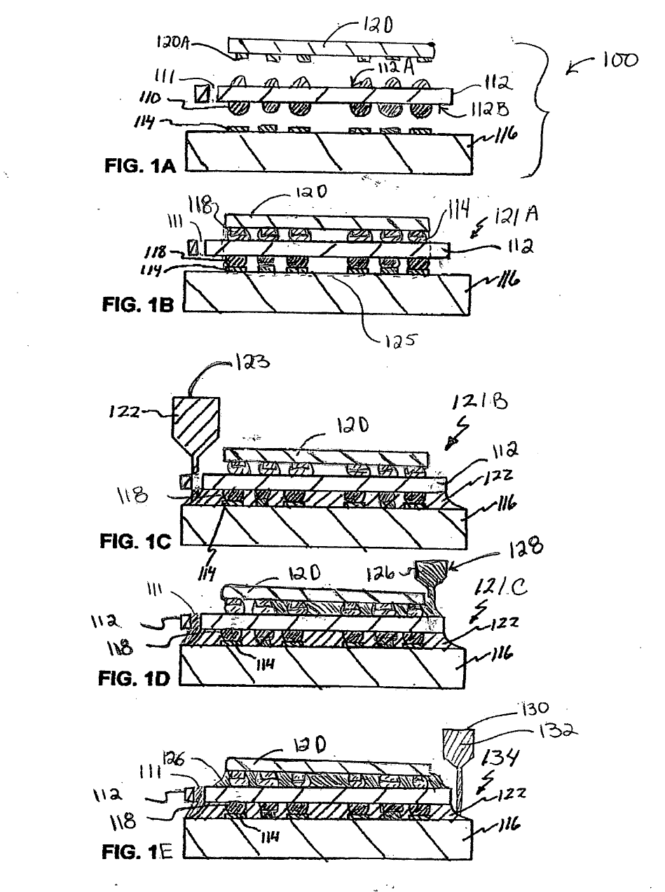

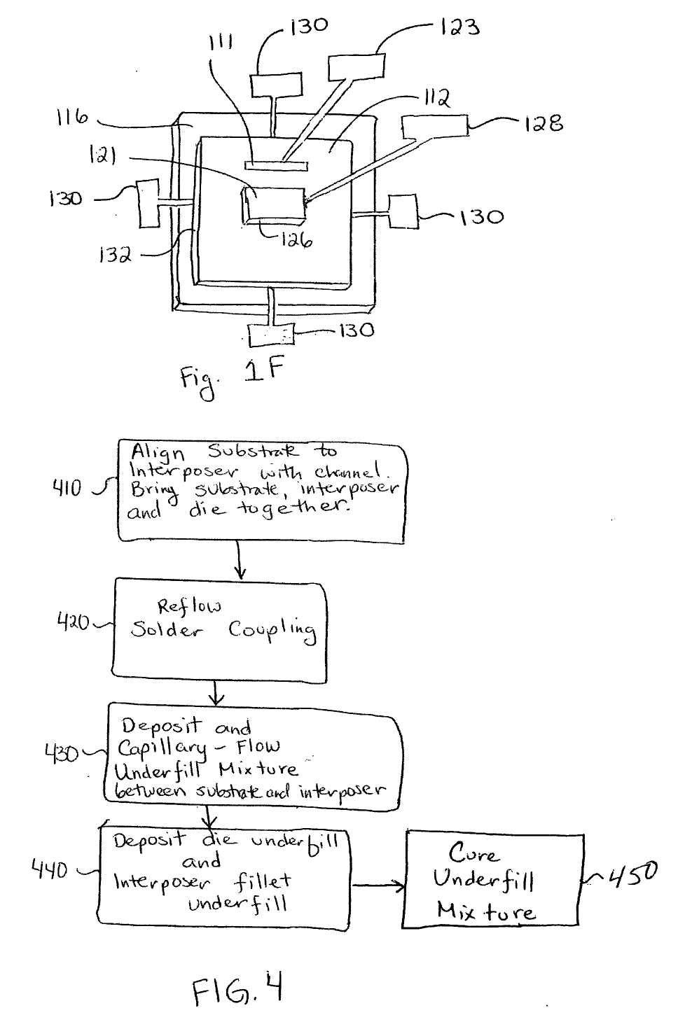

FIG. 1A is a cross-section of a package 100 during a capillary underfill process according to an embodiment. The package 100 includes at least one solder bump 110 that is supported by an interposer 112. The interposer 112 has a channel 111 (or port or passage) that extends through a body of the interposer from a front side 112A through to a back side 112B of the interposer.

Dimensions of the channel 111 depend on a size of the die, and a volume of material dispensed, in one embodiment. In one embodiment, the channel is substantially centered on a longitudinal side of the die. In one embodiment, the channel has a length that is between 50% and 75% of the die length. A width of the channel, in one embodiment, depends upon a volume of the dispensed material. In an additional embodiment, the width of the channel is in a range from about 0.25 mm to about 2 mm.

In one embodiment, the channel 111 is a microchannel that corresponds in size to a nozzle of an underfill dispenser. Electrical coupling for the interposer 112 is accomplished through bond pads 114 that are landed on a mounting substrate 116. The bond pads 114 correspond to the bumps 110. A die 120, such as a semiconductive die, includes bond pads 120A.

FIG. 1B is a cross-section of the package depicted in FIG. 1A after further processing. In FIG. 1B, the interposer 112 and the mounting substrate 116 are aligned and brought together. Next, reflow of the at least one solder bump 110 is carried out. An at least one reflowed solder bump 118 is depicted, and a package assembly 121 A includes the interposer 112 and the mounting substrate 116 as bonded. In one embodiment, the at least one reflowed solder bump includes solder joints which electrically and mechanically couple the interposer and the mounting substrate. The die 120 is aligned to and supported by the interposer 112. In one embodiment, the at least one reflowed solder bump 118 in between the die 120 and the interposer 112 corresponds to the at least one reflowed solder bump 118 in between the interposer 112 and the substrate 116.

In one embodiment, as shown in FIG. 1B, a die shadow region 125 is substantially directly underneath the die 120. The microchannel 111 of the interposer lies outside of the die shadow region 125. In embodiments, the microchannel may be immediately adjacent the die shadow region, or spaced a distance from the die shadow region closer to an edge of the interposer 116, or somewhere in between. In the embodiments shown, the solder bumps 110, reflowed solder bumps 118, and bond pads 114 of the interposer 112 or the die 120 or the substrate 116 all are within the die shadow region 125. In one embodiment, the die shadow region 125 extends from four exterior edges of the die towards the substrate 116.

FIG. 1C is a cross-section of the package assembly depicted in FIG. 1B after further processing. An interposer underfill mixture 122 in an underfill dispenser 123 according to an embodiment is applied to a package assembly 121 B. A nozzle of the dispenser 123 is positioned at the channel 111 to flow underfill mixture 122 using capillary action, in this embodiment.

Capillary conditions cause a wicking action assisting flow of underfill mixture into the region between the interposer 112 and the mounting substrate 116. Capillary flow is the action by which a liquid is drawn towards a solid surface, such as electrical bumps and substrates, because there is a stronger attraction or adhesion between the liquid molecules and the surface particles, than between the liquid molecules themselves. In this embodiment, the liquid underfill material wicks its way through the solder joints and between adjacent surfaces (of the interposer and mounting substrate) until the underfill is complete.

The effectiveness of an underfill mixture or composite depends on its chemical, physical, and mechanical properties. In one embodiment, properties that make an underfill mixture desirable include low CTE, low moisture uptake, high adhesion, high toughness, high glass transition (Tg) temperature, high heat distortion temperature, and others. Capillary conditions that facilitate wicking of the underfill material between two surfaces include the viscosity of the underfill material, the distance between the solid surfaces through which the underfill material flows, the pressure in the spaces to be filled with underfill material, the pressure forcing the underfill material into the spaces, and other conditions.

In this embodiment, the viscosity of the underfill mixture 122 is in a range between 0.5 Pas and 9.0 Pas. In one embodiment, the pressure in the spaces to be filled with underfill material is atmospheric or negative pressure, such as a vacuum draw. In one embodiment, there is a pressure forcing the underfill material into the spaces to be filled.

In one embodiment, the distance between the adjacent surfaces of the interposer and the mounting substrate and the distance between adjacent bumps (or joints) are in a range from about 150 um to about 280 um. In some embodiments, where the distance is less than this range, flow around the electrical bumps may be hindered by the increasingly smaller pitch and/or the increasingly smaller spacing between the substrates. In embodiments where the distance between the substrates and the distance between adjacent bumps exceed this range, flow process may be also be hindered.

The solder joints 118 are reinforced by filling a gap or space between the interposer and mounting substrate, and by filling around the joints, with the underfill mixture 122. In one embodiment, this underfill mixture 122 reduces joint failures due to stress during thermal cycling. In one embodiment, the underfill mixture 122 acts as a CTE intermediary for mismatched CTEs of the interposer and mounting substrate. In one embodiment, the interposer underfill mixture 122 substantially completely fills the volume between interposer 112 and substrate 116 so that the mixture 122 supports and protects the adjacent interposer and substrate at least in the die shadow region.

In one embodiment, capillary underfilling can be assisted by pumping the underfill composite between the substrates, or by vacuum-assisted drawing of the underfill composite between the substrates. The underfill mixture 122 between the interposer 112 and the substrate 116, according to various embodiments, will be described below in greater detail. In another embodiment, the no-flow underfill process, discussed later, is used to dispense the underfill mixture 122 between the interposer and the mounting substrate.

FIG. 1D is a cross-section of the package assembly depicted in FIG. 1C after further processing. A die underfill mixture 126 in a die underfill dispenser 128 according to an embodiment is applied to a package assembly 121 C. A nozzle of the dispenser is positioned adjacent one edge of the die 120. Capillary conditions cause a wicking action assisting flow of underfill mixture 126 into the region between the interposer 112 and the die 120. In one embodiment, the die underfill mixture 126 substantially completely supports and protects the adjacent interposer and die at least in the die shadow region. The underfill mixture 126 between the interposer 112 and the die 120, according to various embodiments, will be described below in greater detail.

FIG. 1E is a cross-section of the package assembly depicted in FIG. 1D after further processing. An interposer fillet dispenser 130 contains an interposer fillet mixture 132 that, according to an embodiment, is applied to a package assembly 134. The interposer fillet mixture 132 is dispensed around the perimeter of the interposer underfill mixture 122 in this embodiment. The interposer fillet mixture 132, according to various embodiments, will be described below in greater detail.

In one embodiment, the fillet mixture is the same as the underfill mixture. In an additional embodiment, the fillet and underfill mixtures are dispensed at different times to optimize flow and reduce risk for entrapped air. In one embodiment, the underfill mixture material is optimized for flow and adhesion. In some embodiments the fillet material may be optimized to allow for increased fracture strength, adhesion, or crack mitigation. In one embodiment, the fillet mixture does not have to flow a tight gap or fine pitch, but does experience the highest stresses. In this embodiment, the fillet mixture is a “tougher” material compared to the underfill mixture at the expense of reduced flow or increased viscosity.

FIG. 1F is a plan view of the package assemblies depicted in FIG. 1C to 1E. As shown in the embodiment of the plan view of FIG. 1F, the fillet dispenser 130 is substantially centered adjacent each of the four side edges of the interposer 112 to dispense the interposer fillet 132. The embodiment of FIG. 1F depicts various positions for dispensers 123, 128, and 130, although other positions are also possible. In each of these embodiments, the dispensers 123, 128, and 130 are shown substantially centered along respective edges or in the microchannel 111, although other non-central positions are also possible.

The microchannel 111 is shown as a rectangular slot in the embodiment of FIG. 1F. In this embodiment, the microchannel is narrow in a first direction. The microchannel is as wide as a side length of the die 120, which is adjacent to the microchannel, in this embodiment. Other configurations and locations of the microchannel are possible in other embodiments.

A curing process is carried out to achieve the package assembly 134. The curing process is carried out according to specific embodiments. In one embodiment, curing the mixture is done by an autocatalytic process. The autocatalytic process is carried out in one embodiment by providing a reactive diluent in the underfill and fillet mixtures 122, 126, 132. In another embodiment, the curing process is carried out by an additive catalytic curing process. The additive catalytic curing process includes an additive such as a metal catalyst powder that causes the fillet and/or underfill mixtures to cure. In another embodiment, a cross-linking/hardening process is carried out to cure the underfill and/or fillet mixtures. Examples of specific cross-linker/hardener composition are set forth herein. In another embodiment, a thermoset curing process is carried out. Typically, several curing process embodiments are assisted by thermal treatment. However, in some embodiments, such as the use of a liquid crystal thermoset monomer, thermoset processing may be done without other curing agent processes.

FIG. 2A is a cross-section of a package assembly 200 during a capillary underfill process according to an embodiment. The package 200 includes at least one solder bump 210 that is attached to an interposer 212. The interposer 212 has a channel 211 that extends from a front side 212a through to a back side 212b of the interposer 212. In one embodiment, the vent hole is round. In an additional embodiment, the diameter of the vent hole is in a range from about 0.1mm to about 2mm. In one embodiment, the channel 211 is a vent hole. Electrical coupling for the interposer 212 is accomplished through bond pads 214 that are landed on a mounting substrate 216. The bond pads 214 correspond to the bumps 210. A die 220, such as a semiconductive die, includes bond pads 220A.

FIG. 2B is a cross-section of the package depicted in FIG. 2A after further processing. In FIG. 2B, the interposer 212 and the mounting substrate 216 are aligned and brought together. Next, reflow of the at least one solder bump 210 is carried out. An at least one reflowed solder bump 218 is depicted, and a package assembly 221A includes the interposer 212 and the mounting substrate 216 as bonded. The die 220 is aligned to and is supported by the interposer 212. In one embodiment, the at least one reflowed solder bump 218 in between the die 220 and the interposer 212 corresponds to the at least one reflowed solder bump 218 in between the interposer 212 and the substrate 216.

In one embodiment, as shown in FIG. 2B, a die shadow region 225 is substantially directly underneath the die 220. The vent hole 211 of the interposer lies within the die shadow region 225. In embodiments, the vent hole 211 may be substantially centered in the interposer, in the midst of the reflowed solder bumps 218, or anywhere in the die shadow region. In the embodiment shown, the solder bumps 210, reflowed solder bumps 218, and bond pads 214 of the interposer 212 or the die 220 or the substrate 216 all are within the die shadow region 225. In one embodiment, the die shadow region 225 extends from four exterior edges of the die towards the substrate 216.

FIG. 2C is a cross-section of the package assembly depicted in FIG. 2B after further processing. An interposer underfill mixture 222 in an underfill dispenser 223 according to an embodiment is applied to a package assembly 221 B. A nozzle of the dispenser 223 is positioned alongside or adjacent an exterior side edge of the interposer 216, as shown and discussed in FIG. 2G.

Capillary conditions cause a wicking action assisting flow of the underfill mixture into the region between the interposer 212 and the mounting substrate 216. In one embodiment, the interposer underfill mixture 222 substantially completely fills the volume between interposer 212 and substrate 216 so that the mixture 222 supports and protects the adjacent interposer and substrate at least in the die shadow region. While the underfill is being flowed in the gap between the interposer and the substrate, the vent hole 211 facilitates the speed of the underfill flow. The vent hole 211 allows air to escape or vent up and out of that gap which removes potentially trapped air and facilitates capillary flow up into the vent hole itself. The speed of the underfill flow is thereby increased.

As shown in FIG. 2F, a meniscus 211a may be formed in the vent hole when the underfill mixture fills up the vent hole. Once the meniscus reaches a certain position in the vent hole, there is no capillary draw of the underfill mixture through the vent hole, and in this embodiment the vent hole is self-limiting in that the flow stops. The underfill mixture 222 between the interposer 212 and the substrate 216, according to various embodiments, will be described below in greater detail.

FIG. 2D is a cross-section of the package assembly depicted in FIG. 2C after further processing. A die underfill mixture 226 in a die underfill dispenser 228 according to an embodiment is applied to a package assembly 221C. A nozzle of the dispenser is positioned adjacent one edge of the die 220. Conditions cause a wicking action of the underfill mixture between the interposer 212 and the die 220. In one embodiment, the die underfill mixture 226 substantially completely supports and protects the adjacent interposer and die at least in the die shadow region. The underfill mixture 226 between the interposer 212 and the die 220, according to various embodiments, will be described below in greater detail.

FIG. 2E is a cross-section of the package assembly depicted in FIG. 2D after further processing. An interposer fillet dispenser 230 contains an interposer fillet mixture 232 that, according to an embodiment, is applied to a package assembly 234. The interposer fillet mixture 232 is dispensed around the perimeter of the interposer underfill mixture 222, in this embodiment. The interposer fillet mixture 232, according to various embodiments, will be described below in greater detail.

FIG. 2F is a view of a meniscus 211a in the vent hole 211 of the interposer 212 according to one embodiment of FIG. 2C.

FIG. 2G is a plan view of the package assembly depicted in FIG. 2C after further processing according to one embodiment. The vent hole 211 is shown in dashed lines under the die 220. The fillet dispensers 223 may be positioned adjacent each of the four side edges of the interposer 212 to dispense the interposer underfill 222. Any number of dispensers 223 may be used, including but not limited to one (1), two (2) or four (4) dispensers 223. In this embodiment, the dispensers 223 are shown substantially centered along respective edges of the interposer 212, although other non-central positions are also possible. Not shown in this plan view are locations of dispensers 228 and 230, which correspond to locations of 128 and 130, respectively.

A curing process of underfill and fillet mixtures 222, 226, 232 is carried out to achieve the package assembly 234 in a manner similar to that as described with respect to FIGS. 1A to 1F.

FIG. 3A is a cross-section of a package assembly 300 after a capillary underfill process according to an embodiment. In one embodiment, the package 300 includes an interposer 312 with bond pads 314, a substrate 316 supporting the interposer, and reflowed solder bumps 318 coupling the bond pads 314 of the interposer with a die 321.

In one embodiment, the interposer 312 has a channel 311a that extends through a channel body from a front side 312a through to a back side 312b of the interposer 312. In one embodiment, the channel 311a corresponds to the vent hole 211 described above. In this embodiment, the interposer 312 further has a micro channel 311b, corresponding to the microchannel 111 described above.

Between the interposer 312 and the substrate 316, and between the solderballs 319, is interposer underfill mixture 322. The underfill mixture 322 is dispensed through the microchannel 311b and capillary conditions cause a wicking action assisting flow of the underfill mixture 322 into the region between the interposer 312 and the mounting substrate 316.

In this embodiment, the channel 311a is a vent hole that lies within the die shadow region. In embodiments, the vent hole 311a may be substantially centered in the interposer, in the midst of the reflowed solder bumps 318, or anywhere in the die shadow region. In the embodiment shown, the reflowed solder bumps 318 and bond pads 314 are within the die shadow region. In one embodiment, the die shadow region extends from four exterior edges of the die towards the substrate 316.

While the underfill is being flowed in a gap between the interposer and the substrate, the vent hole 311a allows air to escape and vent up and out of that gap, thereby increasing the speed of the underfill flow. As shown in FIG. 2F, a meniscus may be formed in the vent hole when the underfill mixture itself fills up the vent hole.

FIG. 3B is a plan view of the package depicted in FIG. 3A. In this embodiment, the vent hole 311a is shown in dashed lines under the die 321. In this embodiment, four (4) microchannels 311b are shown, although there may be any number of microchannels 311b used. In this embodiment, the four microchannels are adjacent each of the four sides of the die, respectively. With four microchannels 311b, four interposer underfill dispensers (not shown) may be used substantially simultaneously to dispense interposer underfill mixture 322. With the vent hole 311a allowing air to escape, the interposer underfill mixture can quickly wick towards the center of the interposer from all four sides.

In an additional embodiment, instead of a die underfill dispenser 128 and 228, a no-flow underfill process is used. However, if a vent hole 211, 311a is used for allowing air to escape from under the interposer, the no-flow underfill process occurs after the interposer underfill is dispensed. If there is only a microchannel 111, 311b, and no vent hole, the no-flow underfill process may occur before or after the interposer underfill is dispensed. A no-flow underfill mixture may be applied either to the die or to the front side of the interposer. Next, the die and the interposer are aligned and brought together to form an assembly. The no-flow underfill mixture is cured, and the solder bump(s) are reflowed.

In one embodiment, the no-flow underfill process uses a no-flow underfill mixture that reduces the bump interconnection yield, because the filler gets deposited between the bumps and the pads such that electrical connections are not achieved.

According to an embodiment, the solder bumps 110 and 210 include substantially Pb-free solder technology. In another embodiment, the solder bumps 110 and 210 are Pb-containing solder. By “substantially Pb-free solder”, it is meant that the solder is not designed with Pb content according to industry trends.

### Underfill Formulations

One embodiment relates to achieving an underfill mixture that includes physical properties of the previously known underfill composites that included inorganic particles. In one embodiment, underfill composites have coefficients of thermal expansion (CTEs) that are between the CTEs of the chip and the board. Accordingly, some embodiments include underfill mixtures that have a range of compositions and combinations.

Some desirable properties of underfill mixtures include a high modulus, low viscosity at the time of dispensing onto a chip (or die) and/or substrate, low CTE and good adhesion to the interfaces post cure, so that no delamination at the interface occurs during device testing and field use. Some other desirable properties of underfill mixtures include a high glass-transition (Tg) temperature, and a low moisture uptake.

According to various embodiments, the principal underfill compositions include at least one of silesquioxanes, thermosetting liquid crystal monomers, and mixtures thereof.

### Additive Materials

Additive materials are included with the principal underfill compositions. The additive materials and the principal underfill compositions constitute “underfill mixtures” according to embodiments set forth herein.

One additive material according to an embodiment is an elastomer for imparting flexibility to the principal underfill composition. Another additive material according to an embodiment is a hardener/crosslinker. The specific hardener/crosslinker that is employed will depend upon compatibility with the principal underfill composition. Hardeners/crosslinkers can be both aromatic and aliphatic in nature. The hardener/crosslinker in one embodiment is an anhydride composition. In another embodiment, the hardener/crosslinker is an amine.

Another additive material according to an embodiment is a catalyst. Another additive material according to an embodiment is a reactive diluent. Another additive material according to an embodiment is an adhesion promoter. Another additive material according to an embodiment is a flow modifier such as a surfactant. Another additive material according to an embodiment is a deforming agent. Another additive material according to an embodiment is a fluxing agent. Another additive material according to an embodiment is a toughening agent. A toughening agent causes the underfill mixture to resist crack propagation. Another additive material according to an embodiment is an inorganic filler. The specific characteristics and composition of the underfill or fillet mixture that is employed will depend upon compatibility with the principal underfill or fillet composition.

### Package Assembly

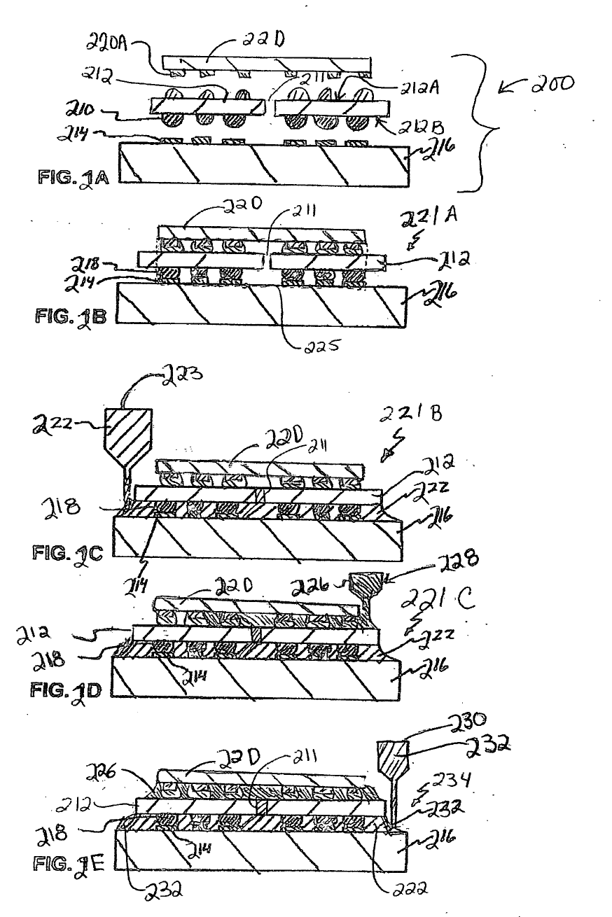

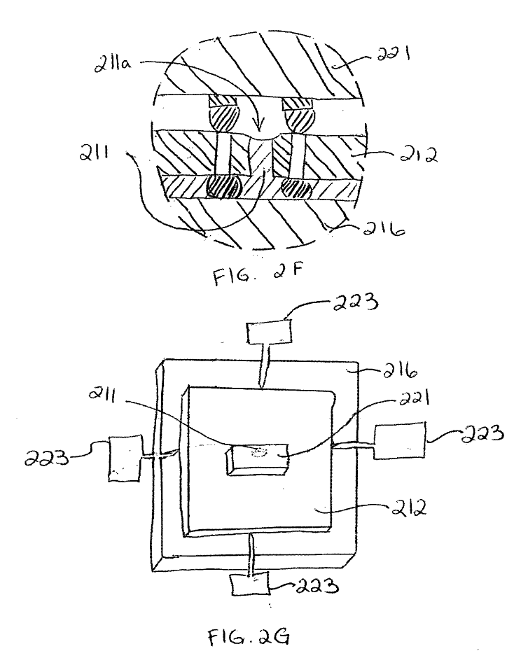

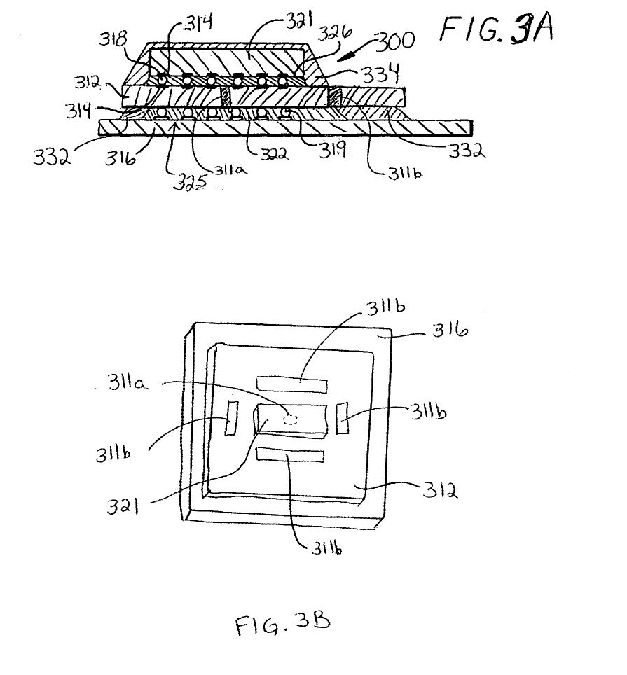

FIG. 4 is a process flow diagram that depicts a packaging process embodiment. In 410, a substrate and an interposer are aligned and brought together, and the die is aligned and brought together with the interposer. In 420, the solder supported by the interposer is reflowed and adhered to the bonding pad on the mounting substrate. The solder is a Pb-free solder in one embodiment, and a Pb-containing solder in another embodiment. In 430, an interposer underfill mixture or an underfill composite as set forth herein is dispensed between the interposer and the substrate using capillary flow. In embodiments set forth herein, the underfill mixture is dispensed through a microchannel in the interposer, or when the underfill mixture is being dispensed, air is allowed to escape via a vent hole in the interposer, or both a microchannel and a vent hole are positioned in the interposer. Capillary conditions cause a wicking action assisting flow of the underfill mixture into the region between the interposer and the mounting substrate. In embodiments, the underfill mixture flows by at least one of capillary action, positive pressure expulsion, or negative pressure (vacuum) draw. In 440, the die underfill is deposited, and the interposer fillet underfill is deposited. The die underfill may be deposited with capillary flow, or a no flow underfill mixture may be used, as discussed above. In 450, the underfill mixture(s) or underfill composite(s), and the fillet underfill mixture are cured. In one embodiment, the cure is a thermal process. In one embodiment, the cure is an autocatalytic process. In one embodiment, the cure is a catalytic process.

It will be readily understood to those skilled in the art that various other changes in the details, material, and arrangements of the parts and method stages which have been described and illustrated in order to explain the nature of this invention may be made without departing from the principles and scope of the invention as expressed in the subjoined claims.

Although the inventive concept may be discussed in the exemplary context of an interposer of a package, the claims are not so limited. Indeed, embodiments of the present invention may well be implemented as part of any package system. The described packages can also be implemented in a number of different embodiments, including an electronic system and a computer system. The elements, materials, geometries, dimensions, and sequence of operations can all be varied to suit particular packaging requirements.

The packaging techniques described herein may be used with a die as described above, or with flash memory, SRAM, and PsuedoSRAM combinations. Therefore, such die packages could be part of system memory as well.

FIGS. 1-4 are merely representational and are not drawn to scale. Certain proportions thereof may be exaggerated, while others may be minimized. Many other embodiments will be apparent to those of skill in the art upon reviewing the above description.

In one embodiment, a package includes a die including an active surface, a substrate electrically coupled with the active surface, and an interposer between the die and the substrate. The interposer has a body with a first surface, an opposite second surface, and a channel passing through the body from the first surface to the second surface.

In one embodiment, a packaging system includes a die, a substrate electrically coupled with the die, an interposer between the die and the substrate, and underfill mixture dispensed between the interposer and the substrate using capillary flow. The interposer has a body with a first surface, an opposite second, surface, and a channel passing through the body from the first surface to the second surface.

In one embodiment, a process includes forming a channel through a channel body from a first surface of an interposer through to an opposite second surface of the interposer, disposing the interposer between a die and a substrate, and dispensing underfill between the interposer and the substrate. The channel is at least one of a vent hole to facilitate capillary flow of the underfill mixture, and a microchannel through which the underfill mixture is dispensed.

It is emphasized that the Abstract is provided to comply with 37 C.F.R. §1.72(b) requiring an Abstract that will allow the reader to quickly ascertain the nature and gist of the technical disclosure. It is submitted with the understanding that it will not be used to interpret or limit the scope or meaning of the claims.

In the foregoing Detailed Description, various features are grouped together in a single embodiment for the purpose of streamlining the disclosure. This method of disclosure is not to be interpreted as reflecting an intention that the claimed embodiments of the invention require more features than are expressly recited in each claim. Rather, as the following claims reflect, inventive subject matter lies in less than all features of a single disclosed embodiment. Thus the following claims are hereby incorporated into the Detailed Description of Embodiments of the Invention, with each claim standing on its own as a separate preferred embodiment.

1. A package comprising:
a die including an active surface;
a substrate electrically coupled with the active surface; and
an interposer between the die and the substrate, wherein the interposer has a body with a first surface, an opposite second surface, and a channel passing through the body from the first surface to the second surface.

2. The package of claim 1 wherein the channel lies in the die shadow region.

3. The package of claim 2 wherein the channel is a vent hole to facilitate capillary flow of underfill mixture dispensed between the interposer and the substrate.

4. The package of claim 3 wherein underfill mixture is dispensed between the interposer and the substrate, wherein a meniscus of the underfill mixture is formed within the vent hole, and the meniscus substantially prevents the underfill from exiting the first surface of the interposer.

5. The package of claim 1 wherein the channel lies outside of a die shadow region.

6. The package of claim 5 wherein the channel is a microchannel through which underfill is dispensed.

7. The package of claim 1 wherein there are at least two channels formed in the interposer.

8. The package of claim 7 wherein the at least two channels in the interposer includes a vent hole within a die shadow region and a microchannel that lies outside of the die shadow region, wherein underfill is dispensed into the microchannel and between the interposer and substrate.

9. A packaging system comprising:
a die;
a substrate electrically coupled with the die;
an interposer between the die and the substrate, wherein the interposer has a body with a first surface, an opposite second surface, and a channel passing through the body from the first surface to the second surface; and
underfill mixture dispensed between the interposer and the substrate using capillary flow.

10. The packaging system of claim 9 wherein the channel is substantially centered in the interposer.

11. The packaging system of claim 9 wherein the channel is a vent hole within a die shadow region.

12. The packaging system of claim 9 wherein the channel lies outside of a die shadow region.

13. The packaging system of claim 12 wherein the die shadow region extends from an active surface of the die through the interposer to the second surface.

14. The packaging system of claim 9 wherein there are at least two channels formed in the interposer, including a channel within a die shadow region, and a channel that lies outside of the die shadow region.

15. A process comprising:
forming a channel through a channel body from a first surface of an interposer through to an opposite second surface of the interposer;
disposing the interposer between a die and a substrate; and
dispensing underfill between the interposer and the substrate, wherein the channel is at least one of a vent hole to facilitate capillary flow of the underfill mixture, and a microchannel through which the underfill mixture is dispensed.

16. The process of claim 15 wherein air escapes from between the interposer and the substrate through the vent hole as the underfill mixture is dispensed.

17. The process of claim 15 wherein the vent hole is substantially centered in the interposer.

18. The process of claim 15 wherein the microchannel lies outside of a die shadow region.

19. The process of claim 18 further comprising positioning an underfill dispenser nozzle to the first surface of the interposer at the channel.

20. The process of claim 19 further comprising positioning an underfill dispenser nozzle adjacent an outer edge of the die to dispense the underfill mixture in the channel.

21. The process of claim 15 further comprising positioning the vent hole within a die shadow region, and positioning an underfill dispenser nozzle adjacent an outer edge of the die to dispense the underfill mixture through the microchannel and between the interposer and the substrate.

22. The process of claim 15 further comprising dispensing the underfill mixture from a plurality of underfill mixture dispensers substantially simultaneously while allowing air to escape from between the substrate and the interposer via the vent hole.

23. The process of claim 22 further comprising forming a plurality of microchannels in the interposer about the die, wherein the plurality of dispensers are positioned at the plurality of microchannels, respectively, to dispense the underfill mixture.
